(19) United States
(12) Patent Application Publication
(10) Pub. No.: US 2026/0163580 A1
(43) Pub. Date: Jun. 11, 2026

(54) ANALOG TO DIGITAL CONVERSION DEVICE AND ANALOG TO DIGITAL CONVERSION METHOD

(71) Applicant: REALTEK SEMICONDUCTOR CORPORATION, HSINCHU (TW)

(72) Inventor: WEI-CIAN HONG, HSINCHU (TW)

(21) Appl. No.: 19/413,225

(22) Filed: Dec. 9, 2025

(30) Foreign Application Priority Data
Dec. 10, 2024 (TW) 113147982

(51) Int. Cl. H03M 1/34

(52) U.S. Cl. CPC H03M 1/34

(57) ABSTRACT

An analog to digital conversion device includes a first slope signal generator circuit, a second slope signal generator circuit, and a comparator circuit. The first slope signal generator circuit is configured to generate a first slope signal, wherein the first slope signal repeatedly ramps up and down within a first voltage range with at least one first slope. The second slope signal generator circuit is configured to generate a second slope signal, wherein the second slope signal repeatedly ramps up and down within a second voltage range with at least one second slope. The comparator circuit is configured to generate an output signal according to the first slope signal, the second slope signal, and an input signal.

### BACKGROUND OF THE INVENTION

### 1. Field of the Invention

The present disclosure relates to an analog to digital conversion device and an analog to digital conversion method, especially to an analog to digital conversion device and an analog to digital conversion method that can reduce operation cycle to increase operation frequency.

### 2. Description of Related Art

Analog to digital converters (ADCs) are commonly used in electronic devices to convert analog signals into digital signals that can be processed by electronic devices. A time-interleaved slope ADC is a type of ADC. However, due to operating conditions of time-interleaved slope ADCs, operation frequency of time-interleaved slope ADCs is limited.

### SUMMARY OF THE INVENTION

In some aspects, an object of the present disclosure is to, but not limited to, provides an analog to digital conversion device and an analog to digital conversion method that makes an improvement to the prior art.

An embodiment of an analog to digital conversion device includes a first slope signal generator circuit, a second slope signal generator circuit, and a comparator circuit. The first slope signal generator circuit is configured to generate a first slope signal, wherein the first slope signal repeatedly ramps up and down within a first voltage range with at least one first slope. The second slope signal generator circuit is configured to generate a second slope signal, wherein the second slope signal repeatedly ramps up and down within a second voltage range with at least one second slope. The comparator circuit is configured to generate an output signal according to the first slope signal, the second slope signal, and an input signal.

An embodiment of an analog to digital conversion method includes: generating a first slope signal by a first slope signal generator circuit, wherein the first slope signal repeatedly ramps up and down within a first voltage range with at least one first slope; generating a second slope signal by a second slope signal generator circuit, wherein the second slope signal repeatedly ramps up and down within a second voltage range with at least one second slope; and generating an output signal according to the first slope signal, the second slope signal, and an input signal by a comparator circuit.

Technical features of some embodiments of the present disclosure make an improvement to the prior art. The analog to digital conversion device and the analog to digital conversion method of the present disclosure can reduce operation cycle to increase operation frequency.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of an analog to digital conversion device of the present disclosure.

FIG. 2 shows an embodiment of a flow diagram of an analog to digital conversion method of the present disclosure.

FIG. 3 shows an embodiment of a timing diagram of an analog to digital conversion device of the present disclosure.

FIG. 4 shows an embodiment of a timing diagram of an analog to digital conversion device of the present disclosure.

### DETAILED DESCRIPTION OF THE PREFERRED EMBODIMENTS

To address limitation of operation frequency in time-interleaved slope analog to digital converters (ADCs) in the prior art, the present disclosure provides an analog to digital conversion device and an analog to digital conversion method, which will be explained in detail as shown below.

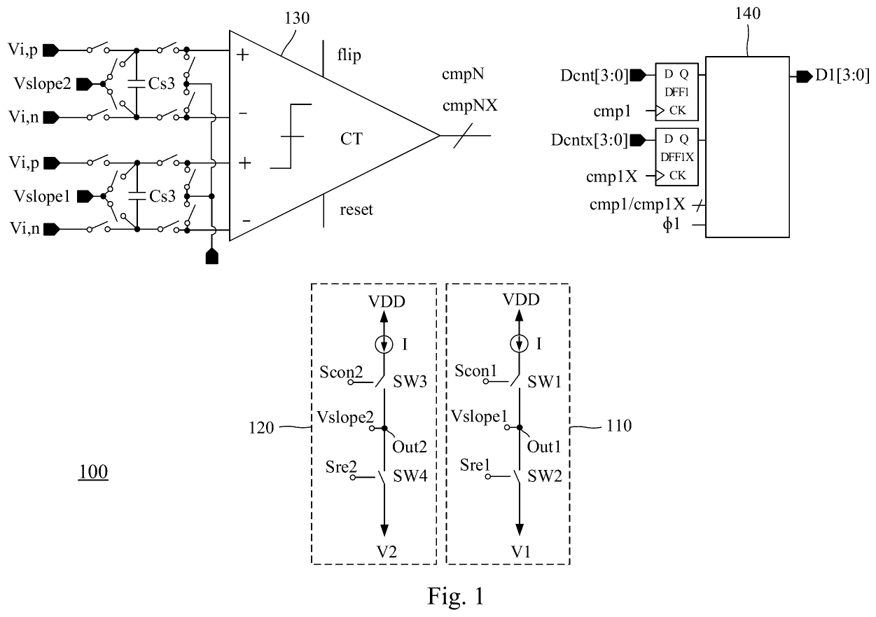

FIG. 1 shows an embodiment of an analog to digital conversion device 100 of the present disclosure. As shown in the figure, the analog to digital conversion device 100 includes a first slope signal generator circuit 110, a second slope signal generator circuit 120, a comparator circuit 130, a capacitor Cs3, flip-flops DFF1, DFF1X, and a digital logic processor 140.

In some embodiments, the analog to digital conversion device 100 may be, but is not limited to, a time-interleaved slope ADC, and the operation of the analog to digital conversion device 100 is described as follows. The analog to digital conversion device 100 may sample an input signal using the capacitor Cs3. Subsequently, the comparator circuit 130 compares the sampled signal with a first slope signal Vslope1 and a second slope signal Vslope2, which are generated by the first slope signal generator circuit 110 and the second slope signal generator circuit 120, respectively. Before the comparator circuit 130 generates a comparison result, a counter continues counting to obtain a count value Dcnt[3:0] until the comparator circuit 130 generates the comparison result. When the positive terminal of the comparator circuit 130 becomes greater than the negative terminal, the output signal cmpN generated by the comparator circuit 130 transitions from low to high. The rising edge of the output signal cmpN transitioning from low to high triggers the flip-flops (e.g., flip-flops DFF1, DFF1X), and the flip-flops store the current count values (e.g., Dcnt[3:0], Dcntx[3:0]) and transmit them to the digital logic processor 140. After being processed by the digital logic processor 140, a data signal D1[3:0] is generated. As described above, the analog to digital conversion device 100 completes a conversion cycle.

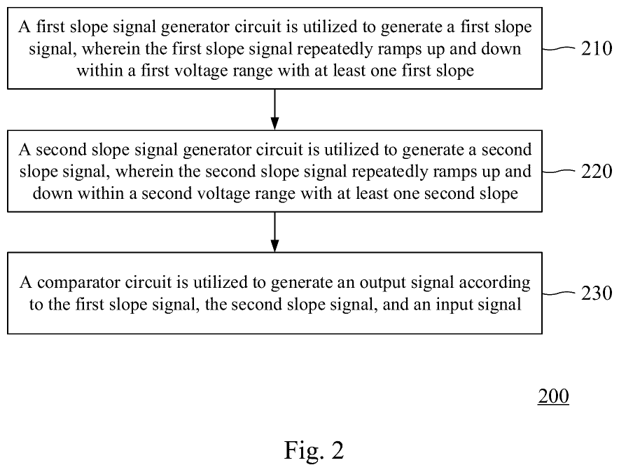

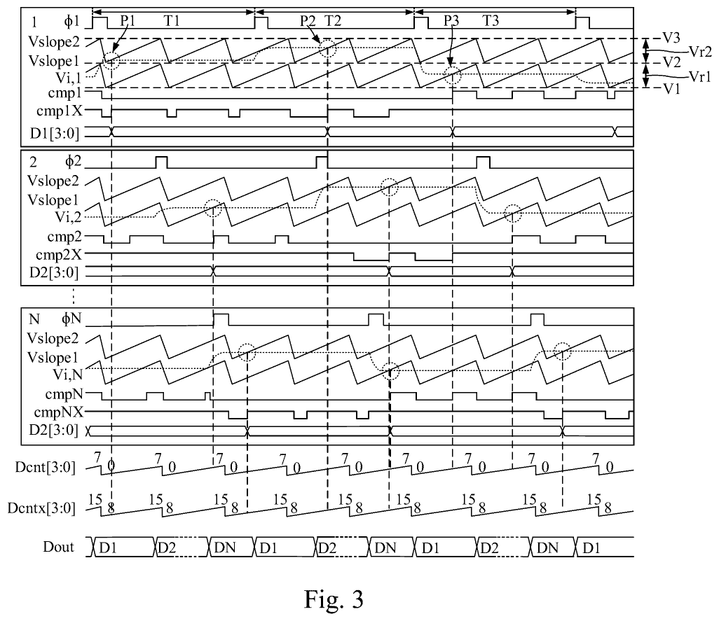

To describe how the analog to digital conversion device 100 of the present disclosure reduces operation cycle to increase operation frequency, please refer to FIG. 2 and FIG. 3. FIG. 2 illustrates a flow diagram of an analog to digital conversion method 200 according to some embodiments of the present disclosure. FIG. 3 illustrates a timing diagram of the analog to digital conversion device 100 according to some embodiments of the present disclosure.

Referring to step 210 of FIG. 2, a first slope signal generator circuit is utilized to generate a first slope signal, wherein the first slope signal repeatedly ramps up and down within a first voltage range with at least one first slope. For example, referring to FIGS. 1, 3, the first slope signal generator circuit 110 generates a first slope signal Vslope1. The first slope signal Vslope1 ramps up with a slope and ramps down with another slope within the first voltage range Vr1 to complete one up-and-down cycle. The first slope signal Vslope1 repeatedly ramps up and down within the first voltage range Vr1 in a periodic manner.

Referring to step 220 of FIG. 2, a second slope signal generator circuit is utilized to generate a second slope signal, wherein the second slope signal repeatedly ramps up and down within a second voltage range with at least one second slope. For example, referring to FIGS. 1, 3, the second slope signal generator circuit 120 generates a second slope signal Vslope2. The second slope signal Vslope2 ramps up with a slope and ramps down with another slope within the second voltage range Vr2 to complete one up-and-down cycle. The second slope signal Vslope2 repeatedly ramps up and down within the second voltage range Vr2 in a periodic manner. In some embodiments, the first slope of the first slope signal Vslope1 during ramp-up may be the same as the second slope of the second slope signal Vslope2 during ramp-up. However, the present disclosure is not limited to the above-mentioned embodiment. The first slope may differ from the second slope, and the first slope and the second slope may be configured according to actual requirements.

Referring to step 230 of FIG. 2, a comparator circuit is utilized to generate an output signal according to the first slope signal, the second slope signal, and an input signal. For example, referring to FIGS. 1, 3, using the input signal Vi, 1 as an example, the comparator circuit 130 generates output signals cmp1, com1X according to the first slope signal Vslope1, the second slope signal Vslope2, and the input signal Vi, 1.

Specifically, referring to cycle T1, at point P1, the comparator circuit 130 generates the output signal com1X according to the second slope signal Vslope2 and the input signal Vi, 1. At this moment, the digital output provides the count result of Dcntx[3:0]. As shown in the figure, point P1 is located in the first half of cycle T1. Referring to cycle T2, at point P2, the comparator circuit 130 generates the output signal com1X according to the second slope signal Vslope2 and the input signal Vi, 1. At this moment, the digital output provides the count result of Dcntx[3:0]. As shown in the figure, point P2 is located in the first half of cycle T2. Referring to cycle T3, at point P3, the comparator circuit 130 generates the output signal com1 according to the first slope signal Vslope1 and the input signal Vi, 1. At this moment, the digital output provides the count result of Dcnt[3:0]. As shown in the figure, point P3 is located in the first half of cycle T3.

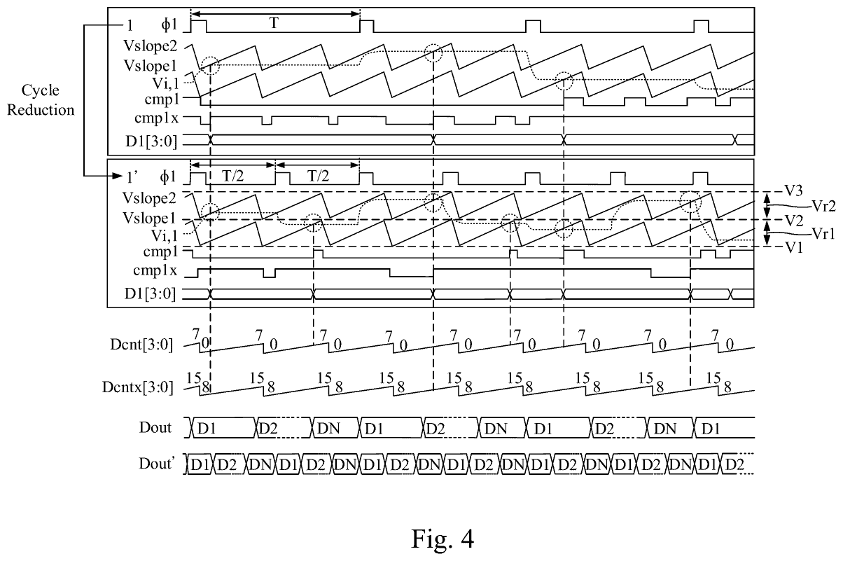

In view of the above, compared to using only a single slope signal, the analog to digital conversion device 100 of the present disclosure uses two slope signals (e.g., the first slope signal Vslope1 and the second slope signal Vslope2), which allows the comparator circuit 130 to generate a comparison result in the first half of the cycle, thereby allowing the digital logic processor 140 to generate a data signal in the first half of the cycle. For example, points P1, P2, P3 are all clearly located in the first halves of cycles T1, T2, T3, respectively. Therefore, the operation timing of the analog to digital conversion device 100 of the present disclosure can be further adjusted to the new timing shown in FIG. 4. As shown in FIG. 4, taking new timing l′ as an example, the cycle T/2 of the new timing of the analog to digital conversion device 100 of the present disclosure is half of the cycle T of the previous timing. As a result, the operation frequency of the analog to digital conversion device 100 of the present disclosure is doubled.

Some embodiments of the present disclosure will be described in detail below. However, the present disclosure is not limited to the embodiments described below, which are merely configured to illustrate the technical concepts of the present disclosure for ease of understanding.

In some embodiments, referring to FIG. 4, a first voltage range Vr1 and a second voltage range Vr2 do not overlap. For example, the first voltage range Vr1 includes a voltage level V1 and a voltage level V2. The first slope signal Vslope1 ramps up from voltage level V1 to voltage level V2 and then ramps down from voltage level V2 to voltage level V1 within the first voltage range Vr1 with a slope. Additionally, the second voltage range Vr2 includes the voltage level V2 and a voltage level V3. The second slope signal Vslope2 ramps up from voltage level V2 to voltage level V3 and then ramps down from voltage level V3 to voltage level V2 within the second voltage range Vr2 with a slope. In this embodiment, the upper voltage level V2 of the first voltage range Vr1 is the same as the lower voltage level V2 of the second voltage range Vr2. Therefore, the first voltage range Vr1 and the second voltage range Vr2 do not overlap. For example, the voltage level V2 may be set to the midpoint between voltage level V1 and voltage level V3. The equation of voltage level V2 is as follows:

$$V 2 = \frac{V 1 + V 3}{2} \qquad Equation 1$$

In some embodiments, the first voltage range Vr1 and the second voltage range Vr2 may partially overlap. For example, based on the embodiment shown in FIG. 4, in another embodiment, the lower voltage level of the first voltage range Vr1 remains at voltage level V1, and the upper voltage level of the first voltage range Vr1 may be adjusted to voltage level V2 plus 50 m V. The lower voltage level of the second voltage range Vr2 may be adjusted to voltage level V2 minus 50 mV, and the upper voltage level of the second voltage range Vr2 remains at voltage level V3. In this embodiment, the upper voltage level (i.e., voltage level V2 plus 50 mV) of the first voltage range Vr1 is different from the lower voltage level (i.e., voltage level V2 minus 50 mV) of the second voltage range Vr2. Therefore, the first voltage range Vr1 and the second voltage range Vr2 partially overlap. It should be noted that the 50 mV is merely an example, and the present disclosure is not limited thereto.

In some embodiments, referring to FIG. 1, the first slope signal generator circuit 110 includes a first output terminal Out1, a first switch SW1, and a second switch SW2. The first switch SW1 includes a first terminal (e.g., upper terminal) and a second terminal (e.g., lower terminal). The first terminal (e.g., upper terminal) of the first switch SW1 is configured to receive a current source current I. The second terminal (e.g., lower terminal) of the first switch SW1 is coupled to the first output terminal Out1. The second switch SW2 includes a first terminal (e.g., upper terminal) and a second terminal (e.g., lower terminal). The first terminal (e.g., upper terminal) of the second switch SW2 is coupled to the first output terminal Out1. The second terminal (e.g., lower terminal) of the second switch SW2 is configured to receive voltage level V1 shown in FIG. 4. The first switch SW1 and the second switch SW2 are configured to output the first slope signal Vslope1 according to a first control signal Scon1 and a first reset signal Sre1. For example, when the first control signal Scon1 is at a high level, the first slope signal Vslope1 gradually charges from voltage level V1 to voltage level V2 as shown in FIG. 4. When the first reset signal Sre1 is at a high level, the first slope signal Vslope1 is reset to voltage level V1.

In some embodiments, referring to FIG. 1, the second slope signal generator circuit 120 includes a second output terminal Out2, a third switch SW3, and a fourth switch SW4. The third switch SW3 includes a first terminal (e.g., upper terminal) and a second terminal (e.g., lower terminal). The first terminal (e.g., upper terminal) of the third switch SW3 is configured to receive a current source current I. The second terminal (e.g., lower terminal) of the third switch SW3 is coupled to the second output terminal Out2. The fourth switch SW4 includes a first terminal (e.g., upper terminal) and a second terminal (e.g., lower terminal). The first terminal (e.g., upper terminal) of the fourth switch SW4 is coupled to the second output terminal Out2. The second terminal (e.g., lower terminal) of the fourth switch SW4 is configured to receive voltage level V2 as shown in FIG. 4. The third switch SW3 and the fourth switch SW4 are configured to output the second slope signal Vslope2 according to a second control signal Scon2 and a second reset signal Sre2. For example, when the second control signal Scon2 is at a high level, the second slope signal Vslope2 gradually charges from voltage level V2 to voltage level V3 as shown in FIG. 4. When the second reset signal Sre2 is at a high level, the second slope signal Vslope2 is reset to voltage level V2.

In some embodiments, referring to FIG. 1, the phase of the first control signal Scon1 is the same as the phase of the second control signal Scon2, and the phase of the first reset signal Sre1 is the same as the phase of the second reset signal Sre2. In another embodiment, the control signal and the reset signal may be grouped into two sets. For example, the first control signal Scon1 and the first reset signal Sre1 may form a first set, and the second control signal Scon2 and the second reset signal Sre2 may form a second set. Phases of the first control signal Scon1 and the first reset signal Sre1 may differ from phases of the second control signal Scon2 and the second reset signal Sre2. In some embodiments, referring to FIG. 1, the number of capacitors Cs3 used in the present disclosure is not limited to two and may be adjusted to other suitable quantities based on actual requirements.

It should be noted that the present disclosure is not limited to the embodiments as shown in FIG. 1 to FIG. 4, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

Technical features of some embodiments of the present disclosure make an improvement to the prior art. The analog to digital conversion device and the analog to digital conversion method of the present disclosure can reduce operation cycle to increase operation frequency.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog to digital conversion device, comprising:
a first slope signal generator circuit, configured to generate a first slope signal, wherein the first slope signal repeatedly ramps up and down within a first voltage range with at least one first slope;
a second slope signal generator circuit, configured to generate a second slope signal, wherein the second slope signal repeatedly ramps up and down within a second voltage range with at least one second slope; and
a comparator circuit, configured to generate an output signal according to the first slope signal, the second slope signal, and an input signal.

2. The analog to digital conversion device of claim 1, wherein the first voltage range and the second voltage range do not overlap.

3. The analog to digital conversion device of claim 1, wherein the first voltage range and the second voltage range partially overlap.

4. The analog to digital conversion device of claim 1, wherein the first voltage range comprises a first low voltage level and a first high voltage level, wherein the first slope signal ramps up from the first low voltage level to the first high voltage level, and then ramps down from the first high voltage level to the first low voltage level within the first voltage range with the at least one first slope.

5. The analog to digital conversion device of claim 4, wherein the second voltage range comprises a second low voltage level and a second high voltage level, wherein the second slope signal ramps up from the second low voltage level to the second high voltage level, and then ramps down from the second high voltage level to the second low voltage level within the second voltage range with the at least one second slope.

6. The analog to digital conversion device of claim 5, wherein the first high voltage level of the first voltage range is the same as the second low voltage level of the second voltage range.

7. The analog to digital conversion device of claim 5, wherein the first high voltage level of the first voltage range is different from the second low voltage level of the second voltage range.

8. The analog to digital conversion device of claim 5, wherein the first slope signal generator circuit comprises:
a first output terminal;
a first switch, comprising:
a first terminal, configured to receive a current source current; and
a second terminal, coupled to the first output terminal; and
a second switch, comprising:
a first terminal, coupled to the first output terminal; and
a second terminal, configured to receive the first low voltage level;
wherein the first switch and the second switch output the first slope signal according to a first control signal and a first reset signal.

9. The analog to digital conversion device of claim 8, wherein the second slope signal generator circuit comprises:
a second output terminal;
a third switch, comprising:
a first terminal, configured to receive the current source current; and
a second terminal, coupled to the second output terminal; and
a fourth switch, comprising:
a first terminal, coupled to the second output terminal; and
a second terminal, configured to receive the second low voltage level;
wherein the third switch and the fourth switch output the second slope signal according to a second control signal and a second reset signal.

10. The analog to digital conversion device of claim 9, wherein phases of the first control signal and the second control signal are identical, and phases of the first reset signal and the second reset signal are identical.

11. An analog to digital conversion method, comprising:
generating a first slope signal by a first slope signal generator circuit, wherein the first slope signal repeatedly ramps up and down within a first voltage range with at least one first slope;
generating a second slope signal by a second slope signal generator circuit, wherein the second slope signal repeatedly ramps up and down within a second voltage range with at least one second slope; and
generating an output signal according to the first slope signal, the second slope signal, and an input signal by a comparator circuit.

12. The analog to digital conversion method of claim 11, wherein the first voltage range and the second voltage range do not overlap.

13. The analog to digital conversion method of claim 11, wherein the first voltage range and the second voltage range partially overlap.

14. The analog to digital conversion method of claim 11, wherein the first voltage range comprises a first low voltage level and a first high voltage level, wherein the first slope signal ramps up from the first low voltage level to the first high voltage level, and then ramps down from the first high voltage level to the first low voltage level within the first voltage range with the at least one first slope.

15. The analog to digital conversion method of claim 14, wherein the second voltage range comprises a second low voltage level and a second high voltage level, wherein the second slope signal ramps up from the second low voltage level to the second high voltage level, and then ramps down from the second high voltage level to the second low voltage level within the second voltage range with the at least one second slope.

16. The analog to digital conversion method of claim 15, wherein the first high voltage level of the first voltage range is the same as the second low voltage level of the second voltage range.

17. The analog to digital conversion method of claim 15, wherein the first high voltage level of the first voltage range is different from the second low voltage level of the second voltage range.

18. The analog to digital conversion method of claim 15, wherein the first slope signal generator circuit comprises a first output terminal, a first switch, and a second switch, wherein a first terminal of the first switch is configured to receive a current source current, a second terminal of the first switch is coupled to the first output terminal, a first terminal of the second switch is coupled to the first output terminal, and a second terminal of the second switch is configured to receive the first low voltage level, wherein generating the first slope signal by the first slope signal generator circuit comprises:
outputting the first slope signal according to a first control signal and a first reset signal by the first switch and the second switch of the first slope signal generator circuit.

19. The analog to digital conversion method of claim 18, wherein the second slope signal generator circuit comprises a second output terminal, a third switch, and a fourth switch, wherein a first terminal of the third switch is configured to receive the current source current, a second terminal of the third switch is coupled to the second output terminal, a first terminal of the fourth switch is coupled to the second output terminal, and a second terminal of the fourth switch is configured to receive the second low voltage level, wherein generating the second slope signal by the second slope signal generator circuit comprises:
outputting the second slope signal according to a second control signal and a second reset signal by the third switch and the fourth switch of the second slope signal generator circuit.

20. The analog to digital conversion method of claim 19, wherein phases of the first control signal and the second control signal are identical, and phases of the first reset signal and the second reset signal are identical.
